(19) United States
(12) Patent Application Publication
(10) Pub. No.: US 2017/0186474 A1
(43) Pub. Date: Jun. 29, 2017

(54) DUAL-CHANNEL DIMM

(71) Applicant: Invensas Corporation, San Jose, CA (US)

(72) Inventors: Belgacem Haba, Saratoga, CA (US); Zhuowen Sun, Campbell, CA (US)

(21) Appl. No.: 14/980,709

(22) Filed: Dec. 28, 2015

(51) Int. Cl. G11C 11/4076; G11C 11/4093

(52) U.S. Cl. CPC G11C 11/4076; G11C 11/4093

(57) ABSTRACT

A dual inline memory module can include a module card having first and second opposed surfaces and a plurality of microelectronic elements each having a surface facing a surface of the module card. The module card can have a plurality of parallel edge contacts, the edge contacts including first and second contacts, the first and second contacts configured to carry command and address information and data signals corresponding to first and second memory channels, respectively, the first memory channel being independent from the second memory channel. Each microelectronic element can have memory storage array function being of type LPDDRx and being configured to sample the command and address information at least twice per clock cycle. The plurality of microelectronic elements can be configured to implement the first and second memory channels. The first and second microelectronic elements can be configured for communication via the first and second contacts, respectively.

### BACKGROUND OF THE INVENTION

The subject matter of the present application relates to dual inline memory modules (“DIMMS”) and microelectronic systems incorporating one or more DIMMS and a circuit panel.

Semiconductor chips are commonly provided as individual, prepackaged units. A standard chip has a flat, rectangular body with a large front face having contacts connected to the internal circuitry of the chip. Each individual chip typically is contained in a package having external terminals connected to the contacts of the chip. In turn, the terminals, i.e., the external connection points of the package, are configured to electrically connect to a circuit panel, such as a printed circuit board. In many conventional designs, the chip package occupies an area of the circuit panel considerably larger than the area of the chip itself. As used in this disclosure with reference to a flat chip having a front face, the “area of the chip” should be understood as referring to the area of the front face.

Size is a significant consideration in any physical arrangement of chips. The demand for more compact physical arrangements of chips has become even more intense with the rapid progress of portable electronic devices. Merely by way of example, devices commonly referred to as “smart phones” integrate the functions of a cellular telephone with powerful data processors, memory, and ancillary devices such as global positioning system receivers, electronic cameras, and local area network connections along with high-resolution displays and associated image processing chips. Such devices can provide capabilities such as full internet connectivity, entertainment including full-resolution video, navigation, electronic banking and more, all in a pocket-size device.

Complex portable devices require packing numerous chips into a small space. Moreover, some of the chips have many input and output connections, commonly referred to as “I/Os.” These I/Os must be interconnected with the I/Os of other chips. The components that form the interconnections should not greatly increase the size of the assembly. Similar needs arise in other applications as, for example, in data servers such as those used in internet search engines where increased performance and size reduction are needed.

Semiconductor chips containing memory storage arrays, particularly dynamic random access memory chips (DRAMs) and flash memory chips, are commonly packaged in single- or multiple-chip packages and assemblies. Each package has many electrical connections for carrying signals, power, and ground between terminals and the chips therein. The electrical connections can include different kinds of conductors such as horizontal conductors, e.g., traces, beam leads, etc., that extend in a horizontal direction relative to a contact-bearing surface of a chip, vertical conductors such as vias, which extend in a vertical direction relative to the surface of the chip, and wire bonds that extend in both horizontal and vertical directions relative to the surface of the chip.

Conventional microelectronic packages can incorporate a microelectronic element that is configured to predominantly provide memory storage array function, i.e., a microelectronic element that embodies a greater number of active devices to provide memory storage array function than any other function. The microelectronic element may be or may include a DRAM chip, or a stacked electrically interconnected assembly of such semiconductor chips.

In light of the foregoing, certain improvements in the design of memory modules or other microelectronic components can be made in order to improve the functional flexibility or electrical performance thereof, particularly in circuit panels or other microelectronic components to which memory modules can be mounted and electrically interconnected with one another.

### BRIEF SUMMARY OF THE INVENTION

A dual inline memory module (“DIMM”) can include a module card having first and second opposed surfaces and a plurality of microelectronic elements each having a surface facing a surface of the first and second surfaces of the module card. The module card can have a plurality of parallel edge contacts adjacent an edge of at least one of the first and second surfaces for mating with corresponding contacts of a socket when the module is inserted in the socket. The edge contacts can include first contacts and second contacts, the first contacts configured to carry command and address information and data signals corresponding to a first memory channel, and the second contacts configured to carry command and address information and data signals corresponding to a second memory channel independent from the first memory channel.

Each microelectronic element can have memory storage array function being of type LPDDRx and can be configured to sample the command and address information at least twice per clock cycle. The plurality of microelectronic elements can include first microelectronic elements configured to implement the first memory channel and second microelectronic elements configured to implement the second memory channel. The first microelectronic elements can be configured for communication via the first contacts, and the second microelectronic elements can be configured for communication via the second contacts.

In one embodiment, the plurality of microelectronic elements can include two first microelectronic elements and two second microelectronic elements. The first contacts can be configured to transfer 32 bits twice per clock cycle to each of the first microelectronic elements, and the second contacts can be configured to transfer 32 bits twice per clock cycle to each of the second microelectronic elements. In a particular example, the first and second microelectronic elements can be arranged in respective first and second stacks. Each of the first microelectronic elements can be configured to receive the command and address information through the same first contacts, and each of the second microelectronic elements can be configured to receive the command and address information through the same second contacts.

In an exemplary embodiment, the surface of each of the microelectronic elements can be arranged in a single common plane parallel to the first surface of the module card. In one example, the plurality of microelectronic elements can include two or more first microelectronic elements and two or more second microelectronic elements. One or more of the first microelectronic elements can be configured to receive the command and address information through a first group of the first contacts, and one or more of the first microelectronic elements can be configured to receive the command and address information through a second group of the first contacts.

In a particular embodiment, the plurality of microelectronic elements can include two first microelectronic elements and two second microelectronic elements. The surface of each of the microelectronic elements can be arranged in a single common plane parallel to the first surface of the module card. Each of the first microelectronic elements can be configured to receive the command and address information through the same first contacts, and each of the second microelectronic elements can be configured to receive the command and address information through the same second contacts. The two first microelectronic elements can have respective first and second delays from the first contacts. The second delay can be greater than the first delay. The two second microelectronic elements can have respective third and fourth delays from the second contacts. The fourth delay can be greater than the third delay.

In one embodiment, the DIMM can also include a registering clock driver (“RCD”) element electrically connected with the first and second contacts, at least one of the first microelectronic elements, and at least one of the second microelectronic elements. The RCD element can be configured to regenerate all of the command and address information received at the first and second contacts. In a particular example, the DIMM can also include a plurality of data buffer elements electrically connected with the first and second contacts, at least one of the first microelectronic elements, and at least one of the second microelectronic elements. Each buffer element can be configured to regenerate all of the data signals received at the first and second contacts.

In an exemplary embodiment, the surface of each of the microelectronic elements can be arranged in a single common plane parallel to the first surface of the module card. The first microelectronic elements can be separated from one another by one of the second microelectronic elements, and the second microelectronic elements can be separated from one another by one of the first microelectronic elements. In one example, the plurality of microelectronic elements can include four first microelectronic elements and four second microelectronic elements. The first contacts can be configured to transfer 16 bits twice per clock cycle to each of the first microelectronic elements, and the second contacts can be configured to transfer 16 bits twice per clock cycle to each of the second microelectronic elements.

In a particular embodiment, the first microelectronic elements can be arranged in first and second stacks, and the second microelectronic elements can be arranged in third and fourth stacks. The microelectronic elements in the first and second stacks can be configured to receive the command and address information through first and second groups of the first contacts, respectively, and the microelectronic element in the third and fourth stacks can be configured to receive the command and address information through third and fourth groups of the second contacts, respectively. In one embodiment, the first microelectronic elements can be arranged in first and second stacks, and the second microelectronic elements can be arranged in third and fourth stacks. The microelectronic elements in the first and second stacks can be configured to receive the command and address information and the data signals through first and second groups of the first contacts, respectively, and the microelectronic element in the third and fourth stacks can be configured to receive the command and address information and the data signals through third and fourth groups of the second contacts, respectively. Each of the stacks can be configured to provide sequential dual rank access to memory storage array locations in the respective stack.

In a particular example, each of the microelectronic elements in the first stack can be configured to receive the command and address information and data signals through the same first contacts in the first group, and each of the microelectronic elements in the second stack can be configured to receive the command and address information and data signals through the same first contacts in the second group. Each of the microelectronic elements in the third stack can be configured to receive the command and address information and data signals through the same second contacts in the third group, and each of the microelectronic elements in the fourth stack can be configured to receive the command and address information and data signals through the same second contacts in the fourth group.

In an exemplary embodiment, the plurality of microelectronic elements can include two first microelectronic elements, two second microelectronic elements, a first ECC microelectronic element, and a second ECC microelectronic element. The first contacts can be configured to transfer 32 bits twice per clock cycle to each of the first microelectronic elements and 8 bits twice per clock cycle to the first ECC microelectronic element. The second contacts can be configured to transfer 32 bits twice per clock cycle to each of the second microelectronic elements and 8 bits twice per clock cycle to the second ECC microelectronic element. In one example, the plurality of parallel edge contacts can include at least 288 parallel edge contacts.

In a particular embodiment, the command signals can be write enable, row address strobe, column address strobe, activate, and parity signals. In one embodiment, each of the microelectronic elements can embody a greater number of active devices to provide memory storage array function than any other function. In a particular example, a system can include the DIMM as described above, a circuit panel, and a processor. The edge contacts of the DIMM can be inserted into a mating socket electrically connected with the circuit panel. In an exemplary embodiment, a system can include the DIMM as described above and one or more other electronic components electrically connected to the DIMM. In one example, the system can also include a housing, the DIMM and the one or more other electronic components being assembled with the housing.

### BRIEF DESCRIPTION OF THE DRAWINGS

FIG. 1A is a side view of a dual inline memory module (“DIMM”) according to an embodiment of the present invention.

FIG. 1B is a diagrammatic representation of the electrical connections within the DIMM shown in FIG. 1A.

FIGS. 2A and 2B are a side view of a DIMM and a diagrammatic representation of the electrical connections within the DIMM, respectively, according to a variation of the DIMM of FIGS. 1A and 1B.

FIGS. 3A and 3B are a side view of a DIMM and a diagrammatic representation of the electrical connections within the DIMM, respectively, according to another variation of the DIMM of FIGS. 1A and 1B having a fly-by command and address signal bus.

FIGS. 4A and 4B are a side view of a DIMM and a diagrammatic representation of the electrical connections within the DIMM, respectively, according to yet another variation of the DIMM of FIGS. 1A and 1B having a registering clock driver.

FIGS. 5A and 5B are a side view of a DIMM and a diagrammatic representation of the electrical connections within the DIMM, respectively, according to a variation of the DIMM of FIGS. 4A and 4B having a plurality of data buffer elements.

FIGS. 6A and 6B are a side view of a DIMM and a diagrammatic representation of the electrical connections within the DIMM, respectively, according to a variation of the DIMM of FIGS. 2A and 2B having an interleaved configuration of microelectronic elements.

FIGS. 7A and 7B are a side view of a DIMM and a diagrammatic representation of the electrical connections within the DIMM, respectively, according to a variation of the DIMM of FIGS. 1A and 1B having 16-bit microelectronic elements.

FIGS. 8A and 8B are a side view of a DIMM and a diagrammatic representation of the electrical connections within the DIMM, respectively, according to another variation of the DIMM of FIGS. 1A and 1B having a dual rank configuration.

FIGS. 9A and 9B are a side view of a DIMM and a diagrammatic representation of the electrical connections within the DIMM, respectively, according to a variation of the DIMM of FIGS. 3A and 3B also having ECC microelectronic elements.

FIG. 10A is a side view of a module card that can be used in any of the embodiments of FIGS. 1A through 8B.

FIG. 10B is a chart of the number of pins assigned to various functions according to a variation of the embodiment of FIGS. 1A and 1B.

FIG. 11 is a schematic depiction of a system according to one embodiment of the invention.

### DETAILED DESCRIPTION

Certain embodiments of the invention provide a dual inline memory module (“DIMM”) in which a microelectronic element, e.g., a semiconductor chip, or stacked arrangement of semiconductor chips, is configured to predominantly provide a memory storage array function. In such microelectronic element, the number of active devices, e.g., transistors, therein that are configured, i.e., constructed and interconnected with other devices, to provide memory storage array function, is greater than the number of active devices that are configured to provide any other function. Thus, in one example, a microelectronic element such as a DRAM chip may have memory storage array function as its primary or sole function.

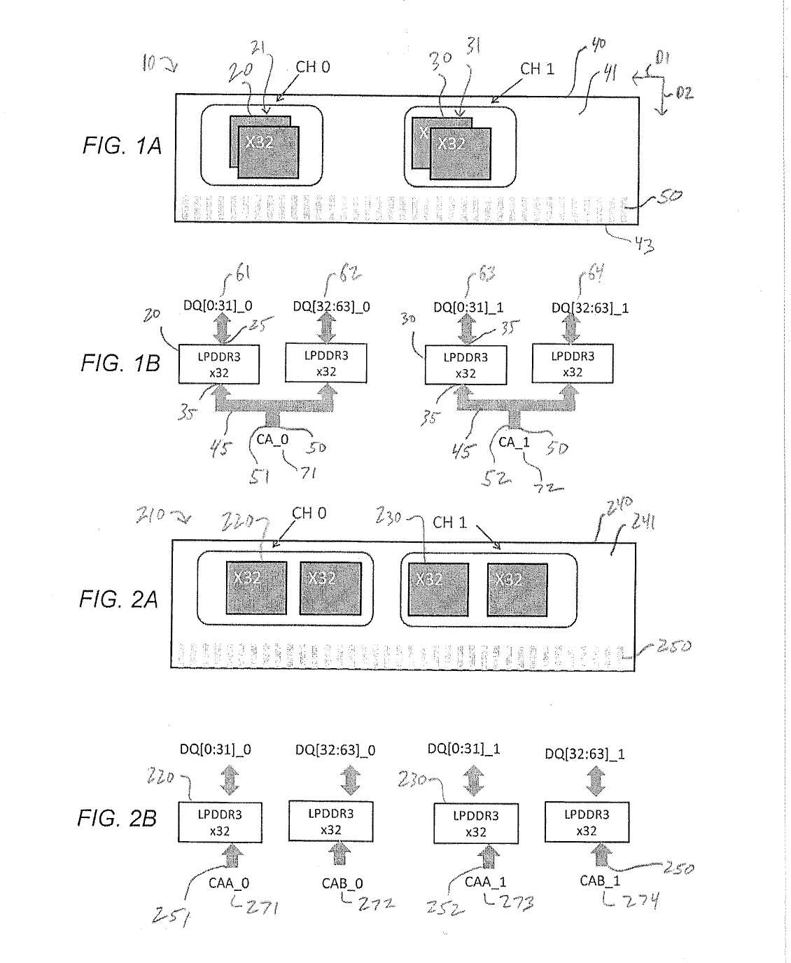

FIGS. 1A and 1B illustrate a particular type of DIMM 10 according to an embodiment of the invention. As seen in FIG. 1A, the DIMM 10 can include first microelectronic elements 20 and second microelectronic elements 30 mounted to a module card 40 having parallel edge contacts 50. An encapsulant (not shown) can optionally cover, partially cover, or leave uncovered rear surfaces of the microelectronic elements 20, 30 and a portion of the module card 40. For example, such an encapsulant can be flowed, stenciled, screened or dispensed onto the rear surfaces of the microelectronic elements 20, 30.

In some embodiments, the first and second microelectronic elements 20, 30 can each be a semiconductor chip, a wafer, or the like. For example, the microelectronic elements 20, 30 can each comprise a memory storage element such as a dynamic random access memory (“DRAM”) storage array or that is configured to predominantly function as a DRAM storage array (e.g., a DRAM integrated circuit chip). As used herein, a “memory storage element” refers to a multiplicity of memory cells arranged in an array, together with circuitry usable to store and retrieve data therefrom, such as for transport of the data over an electrical interface. In one example, each of the microelectronic elements 20, 30 can have memory storage array function. In a particular embodiment, each microelectronic element 20, 30 can embody a greater number of active devices to provide memory storage array function than any other function.

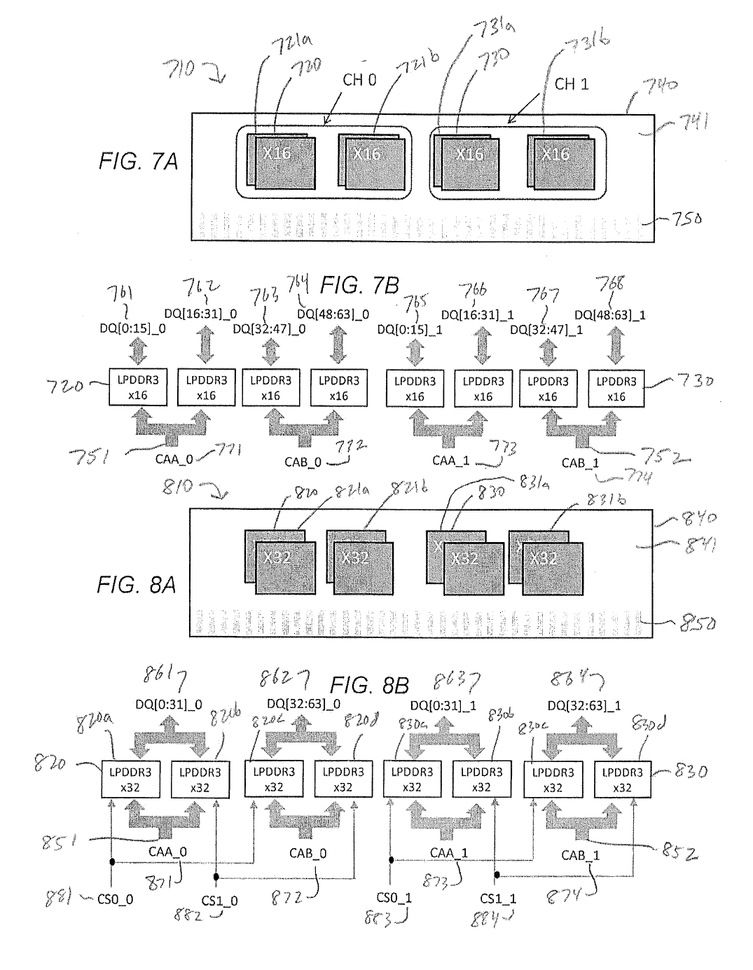

The microelectronic elements 20, 30 can be configured in accordance with one of several different standards, e.g., standards of JEDEC, which specify the type of signaling that semiconductor chips (such as the microelectronic elements 20, 30) transmit and receive through the element contacts 25, 35 thereof. In one example, each of the first and second microelectronic elements 20, 30 can have memory storage array function of type LPDDRx, and can be configured to sample command and address information at least twice per clock cycle. More specifically, each of the microelectronic elements 20, 30 can be of LPDDRx type, i.e., configured in accordance with one of the JEDEC low power double data rate DRAM standards LPDDR3 or one or more of its follow-on standards (collectively, “LPDDRx”). LPDDRx type DRAM chips are available that have 32 contacts assigned to transmit and receive bi-directional data signals, each such bi-directional signal referred to as a “DQ” signal (e.g., FIGS. 1A and 1B) or 16 contacts assigned to carry DQ signals (e.g, FIGS. 7A and 7B). Alternatively, the element contacts 25, 35 can be configured to carry uni-directional data signals such as data signals or “D” signals input to the package and data signals “Q” output from the package, or can be configured to carry a combination of bi-directional and uni-directional data signals.

In one example, at least some of the element contacts 25, 35 can be configured to carry address information. For example, when the microelectronic elements 20, 30 include or are DRAM semiconductor chips, these element contacts can be configured to carry sufficient address information transferred to the microelectronic element that is usable by circuitry within the microelectronic element, e.g., row address and column address decoders, and bank selection circuitry to determine an addressable memory location from among all the available addressable memory locations of a memory storage array within the microelectronic element.

In a particular example, at least some of the element contacts 25, 35 can be configured to carry command signals transferred to the microelectronic elements 20, 30. These element contacts can be configured to carry each of a group of signals of a command-address bus of the microelectronic element; i.e., command signals, address signals, bank address signals, and clock signals that are transferred to the microelectronic package, wherein the command signals include write enable, row address strobe, column address strobe, activate, and parity signals, and the clock signals are clocks used for sampling the address signals. While the clock signals can be of various types, in one embodiment, the clock signals carried by these terminals can be one or more pairs of differential clock signals received as differential or true and complement clock signals.

In one example, at least some of the element contacts 25, 35 can be configured to carry one or more of data strobe signals, or other signals or reference potentials such as chip select, reset, power supply voltages, e.g., Vdd, Vddq, and ground, e.g., Vss and Vssq. The microelectronic elements 20, 30 may include least some element contacts 25, 35 assigned to carry data signals and also data masks and “on die termination” (ODT) signals used to turn on or off parallel terminations to termination resistors.

Each element contact 25, 35 on a LPDDRx type DRAM chip may be used to simultaneously carry two different signals in interleaved fashion. For example, each element contact 25, 35 on such DRAM chip can be assigned to carry one signal that is sampled on the rising edge of the clock cycle and can also be assigned to carry another signal that is sampled on the falling edge of the clock cycle. Thus, in LPDDRx type chips, each microelectronic element 20, 30 can be configured to sample the command and address information input to the element contacts thereof at a sampling rate such as twice per clock cycle (e.g., on both the rising edge and on the falling edge of the clock cycle). Accordingly, the number of contacts on the LPDDRx DRAM chip that carry address information or command-address bus information can be reduced compared to microelectronic elements having memory storage array function of type DDRx (i.e., configured in accordance with one of the JEDEC double data rate DRAM standards DDR3, DDR4, or one or more of their follow-on standards).

Each microelectronic element 20, 30 can have a front surface, a rear surface remote therefrom, and lateral edges each extending between the front and rear surfaces, and can have element contacts 25, 35 (FIG. 1B) at the respective front surface. As described herein, the element contacts 25, 35 of the microelectronic elements 20, 30 can also be referred to as “chip contacts.” In one example, the element contacts 25, 35 of each of the first and second microelectronic elements 20, 30 can be at the respective front surface within a central region thereof. For example, the element contacts 25, 35 can be arranged in one or two parallel rows adjacent the center of the front surface.

As used in this disclosure with reference to a component, e.g., an interposer, microelectronic element, circuit panel, substrate, etc., a statement that an electrically conductive element is “at” a surface of a component indicates that, when the component is not assembled with any other element, the electrically conductive element is available for contact with a theoretical point moving in a direction perpendicular to the surface of the component toward the surface of the component from outside the component. Thus, a terminal or other conductive element which is at a surface of a substrate may project from such surface; may be flush with such surface; or may be recessed relative to such surface in a hole or depression in the substrate.

As can be seen in FIG. 1A, the first and second microelectronic elements 20, 30 can each be arranged in respective first and second stacks 21, 31 overlying a first surface 41 of the module card 40. As shown, the microelectronic elements 20 in the first stack 21 are arranged partially offset from one another in first and second transverse directions D1, D2 parallel to the first surface 41 of the module card, and the microelectronic elements 30 in the second stack 31 are arranged partially offset from one another the first and second transverse directions. In other examples, the microelectronic elements 20, 30 within each of the first and second stacks 21, 31 can have any relative arrangement relative to one another, either with the chips aligned with one another in the first and second transverse directions D1, D2 (both chips face-up, both chips face-down, or one face-up and one face-down), or with the chips offset in one or both of the first and second transverse directions (also with both chips face-up, both chips face-down, or one face-up and one face-down).

In FIG. 1A, the first and second transverse directions D1, D2 parallel to the first surface 41 of the module card 40 are referred to herein as “horizontal” or “lateral” directions, whereas the directions perpendicular to the first surface are referred to herein as upward or downward directions and are also referred to herein as the “vertical” directions. The directions referred to herein are in the frame of reference of the structures referred to. Thus, these directions may lie at any orientation to the normal “up” or “down” directions in a gravitational frame of reference.

A statement that one feature is disposed at a greater height “above a surface” than another feature means that the one feature is at a greater distance in the same orthogonal direction away from the surface than the other feature. Conversely, a statement that one feature is disposed at a lesser height “above a surface” than another feature means that the one feature is at a smaller distance in the same orthogonal direction away from the surface than the other feature.

The element contacts 25, 35 of the microelectronic elements 20, 30 within each of the first and second stacks 21, 31 can be electrically connected with the edge contacts 50 via electrically conductive leads 45 (FIG. 1B). Each of the first and second microelectronic elements 20, 30 in the first and second stacks 21, 31 can be electrically connected with conductive elements of the module card 40 via any type of electrically conductive leads 45, such as flip-chip mounting with joining elements (e.g, solder), conductive posts, face-up or face-down wire-bonds, lead bonds, or the like. In some embodiments, such joining elements can be, for example, masses of a bond metal such as solder, tin, indium, a eutectic composition or combination thereof, or another joining material such as an electrically conductive paste, an electrically conductive adhesive or electrically conductive matrix material or a combination of any or all of such bond metals or electrically conductive materials.

As used herein, a “lead” is a portion of or the entire electrical connection extending between two electrically conductive elements, such as a lead 45 that extends from one of the element contacts 25 of one the first microelectronic elements 20 to one of the edge contacts 50. For example, a lead such as the lead 45 can include a wire bond and a conductive trace on the module card 40 extending from an element contact 25 or 35 to an edge contact 50. In some examples, the leads 45 can have portions extending through bond windows of the module card 40, for example, the first and second microelectronic elements 20, 30 can be connected with conductive elements at a second surface of the module card opposite the first surface 41 via wire bonds extending through one or more bond windows. In some embodiments, the upper microelectronic elements 20, 30 in the first and second stacks 21, 31 can be electrically connected with conductive elements of the module card either directly (e.g., wire bonds, flip-chip mounting) or indirectly, for example, by through-silicon vias (“TSVs”) extending through the lower microelectronic elements, by traces extending along peripheral edge surfaces of the lower microelectronic elements, or the like.

The microelectronic assembly 10 can further include a module card 40 having a first surface 41 and a second surface opposite the first surface. As shown in FIG. 1A, a surface of each of the first and second microelectronic elements 20, 30 can face the first surface 41 of the module card 40. In other example, a surface of one or more of the first and second microelectronic elements 20, 30 can face the second surface of the module card 40, such that one or more of the microelectronic elements are mounted to the first surface and one or more of the microelectronic elements are mounted to the second surface.

The module card 40 can be partly or entirely made of any suitable dielectric material. For example, the module card 40 may comprise a relatively rigid, board-like material such as a thick layer of fiber-reinforced epoxy, such as Fr-4 or Fr-5 board. Regardless of the material employed, the module card 40 may include a single layer or multiple layers of dielectric material. In a particular embodiment, the module card 40 can consist essentially of a material having a coefficient of thermal expansion (“CTE”) of less than 30 ppm/° C.

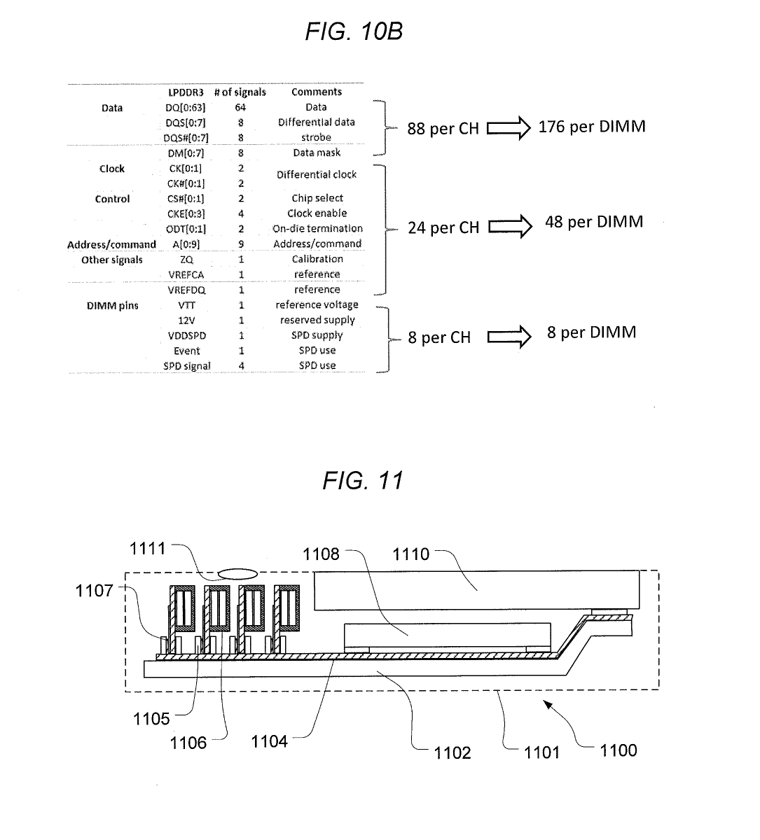

The module card 40 may also include electrically conductive module contacts at at least one of the first and second surfaces thereof and electrically conductive leads 45 extending between the module contacts and the edge contacts 50. The leads 45 can electrically couple the module contacts to the exposed edge contacts 50. In a particular embodiment, the module contacts can be end portions of respective ones of the leads 45. The module card 40 can have a plurality of parallel edge contacts 50 adjacent an insertion edge 43 of at least one of the first and second surfaces for mating with corresponding contacts of a socket (e.g., the socket 1005 in FIG. 10) when the DIMM 10 is inserted in the socket. Some or all of the edge contacts 50 can be exposed at either or both of the first and second surfaces of the module card 40. In the embodiment of FIGS. 1A and 1B (and the other embodiments described herein), the DIMM 10 can include at least 288 parallel edge contacts 50 adjacent the insertion edge 43 of at least one of the first and second surfaces of the module card 40. In some examples, the DIMM 10 (and many of the other DIMMs described herein) can include exactly 288 parallel edge contacts 50.

The edge contacts 50 and the insertion edge 43 can be sized for insertion into a corresponding socket (FIG. 10) of other connector of a system, such as can be provided on a motherboard. Such edge contacts 50 can be suitable for mating with a plurality of corresponding spring contacts (e.g., the spring contacts 1007 in FIG. 10) within such socket connector. Such spring contacts can be disposed on single or multiple sides of each slot to mate with corresponding ones of the edge contacts 50. In one example, at least some of the edge contacts 50 can be usable to carry at least one of a signal or a reference potential between the respective edge contact and at least one of the first and second microelectronic elements 20, 30.

The edge contacts 50 can include first contacts 51 and second contacts 52. The first contacts 51 can be configured to carry command and address information and data signals corresponding to a first memory channel (labeled “CH 0” in FIG. 1A), and the second contacts 52 can be configured to carry command and address information and data signals corresponding to a second memory channel (labeled “CH 1” in FIG. 1A) independent from the first memory channel. In the exemplary embodiment of FIGS. 1A and 1B, the first microelectronic elements 20 in the first stack 21 can be configured to implement the first memory channel CH 0, and the second microelectronic elements 30 in the second stack 31 can be configured to implement the second memory channel CH 1. The first microelectronic elements 30 can be configured for communication via the first contacts 51, and the second microelectronic elements 40 can be configured for communication via the second contacts 52.

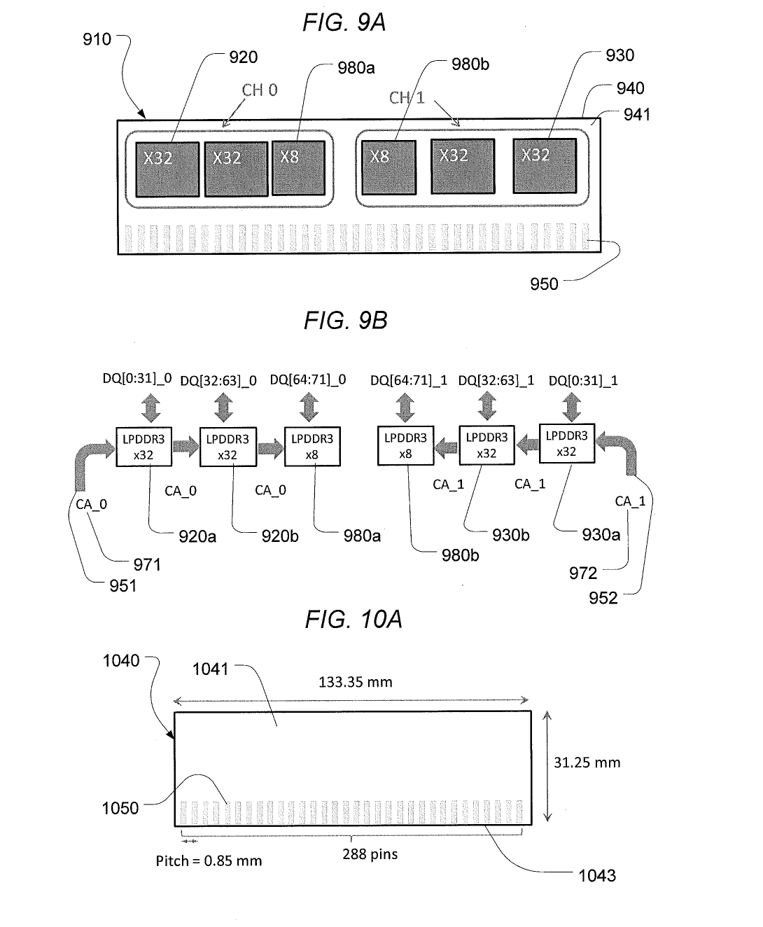

In the example of FIGS. 1A and 1B, the DIMM 10 can include two first microelectronic elements 20 and two second microelectronic elements 30. The first contacts 51 can be configured to transfer 32 bits twice per clock cycle to each of the first microelectronic elements 20, and the second contacts 52 can be configured to transfer 32 bits twice per clock cycle to each of the second microelectronic elements 30. This can be seen in FIG. 1B, in which the contacts 50 can include four 32-bit groups of data contacts 61, 62, 63, and 64, labeled in FIG. 1B as DQ(0:31)_0, DQ(32:63)_0, DQ(0:31)_1, and DQ(32:63)_1, respectively. In one example (shown in FIG. 9B), the four groups of data contacts 61, 62, 63, and 64 canoccupy 128 contacts (64 per channel) of the at least 288 edge contacts 50.

Each of the groups of data contacts 61, 62, 63, and 64 can be configured to transfer 32 bits twice per clock cycle to a corresponding one of the microelectronic elements 20, 30. Data contact groups 61 and 62 comprise a first 64-bit set of data contacts configured to transfer 64 bits twice per clock cycle to the first stack 21, configured to implement the first memory channel CH 0. Data contact groups 63 and 64 comprise a second 64-bit set of data contacts configured to transfer 64 bits twice per clock cycle to the second stack 31, configured to implement the second memory channel CH 1.

In the example of FIGS. 1A and 1B, the edge contacts 50 can also include two groups of command and address information contacts (“CA contacts”) 71 and 72, labeled in FIG. 1B as CA_0 and CA_1, respectively. In one example (shown in FIG. 9B), the two groups of CA contacts 71 and 72 can occupy 48 contacts (24 per channel) of the at least 288 edge contacts 50. As can be seen in FIG. 1B, each of the first microelectronic elements 20 can be configured to receive the command and address information through the same CA contacts 71 of the first contacts 51, and each of the second microelectronic elements 30 can be configured to receive the command and address information through the same CA contacts 72 of the second contacts 52.

FIGS. 2A and 2B illustrate a DIMM 210, according to a variation of the DIMM 10 of FIGS. 1A and 1B. Elements of the DIMM 210 that are not specifically described below can be the same as those described above with respect to the DIMM 10. The DIMM 210 has first and second microelectronic elements 220, 230, but rather than being arranged in stacks, a surface of each of the first and second microelectronic elements can be arranged in a single common plane parallel to the first surface 241 of the module card 240.

The DIMM 210 has edge contacts 250 that can include four groups of CA contacts 271, 271, 273, and 274, labeled in FIG. 2B as CAA_0, CAB_0, CAA_1, and CAB_1, respectively. In one example, the four groups of CA contacts 271, 272, 273, and 274 can occupy 96 contacts (24 per CA contact group, 48 per channel) of the at least 288 edge contacts 250. As can be seen in FIG. 2B, each of the first microelectronic elements 220 can be configured to receive the command and address information through separate respective groups of CA contacts 271, 272 of the first contacts 251, and each of the second microelectronic elements 230 can be configured to receive the command and address information through separate respective groups of CA contacts 273, 274 of the second contacts 252. In a particular embodiment, one or more of the first microelectronic elements 220 can be configured to receive command and address information through a first group 271 of the first contacts 251, and one or more of the first microelectronic elements can be configured to receive the command and address information through a second group 272 of the first contacts.

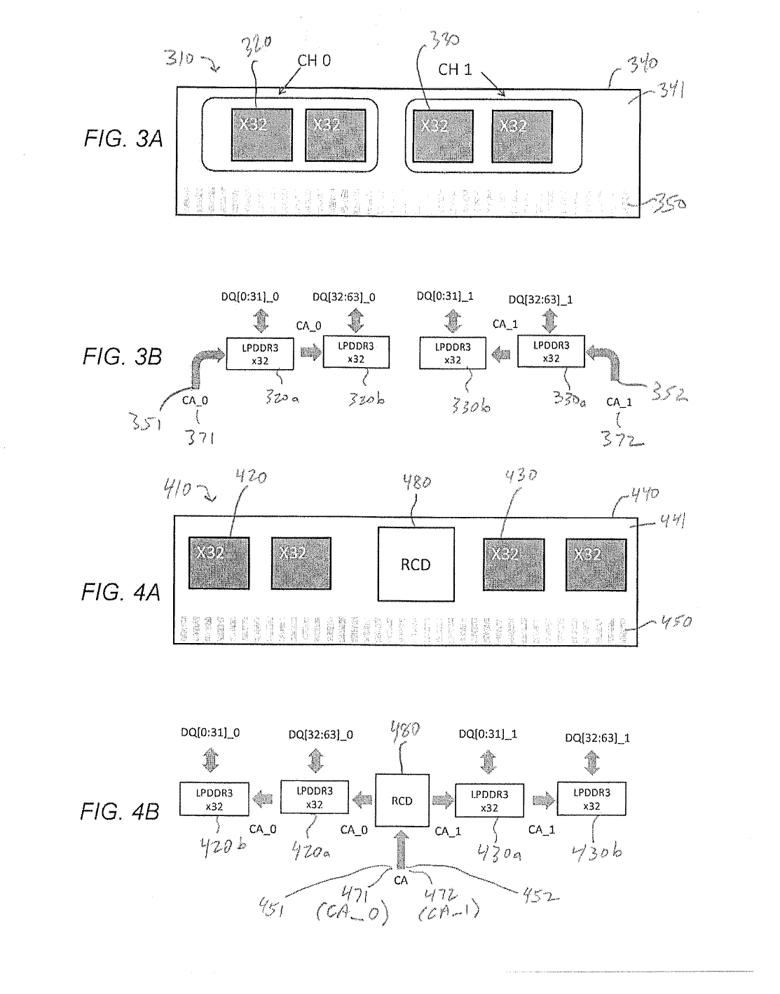

FIGS. 3A and 3B illustrate a DIMM 310, according to another variation of the DIMM 10 of FIGS. 1A and 1B. Elements of the DIMM 310 that are not specifically described below can be the same as those described above with respect to the DIMM 10. The DIMM 310 has first and second microelectronic elements 320, 330 arranged in a single common plane parallel to the first surface 341 of the module card 340, similar to the arrangement of first and second microelectronic elements 220, 320 of the DIMM 210.

FIGS. 3A and 3B illustrate principles of interconnection that support an in-module “fly-by” CA signaling configuration in a drawing that has been simplified for ease of explanation and illustration. One characteristic that can be achieved in accordance with an embodiment as seen in FIGS. 3A and 3B is to provide in-module fly-by address signaling, in that a difference between the first and second delays along CA signal lines on the module card 340 is greater than a difference in the delay along the CA lines between the edge contacts 350 and any two address inputs of a first microelectronic element 320a, or for example, between the edge contacts and any two address inputs of another first microelectronic element 320b.

In the example of FIGS. 3A and 3B, the edge contacts 350 can include two groups of command and address information contacts (“CA contacts”) 371 and 372, labeled in FIG. 3B as CA_0 and CA_1, respectively. In one example (shown in FIG. 9B), the two groups of CA contacts 371 and 372 can occupy 48 contacts (24 per channel) of the at least 288 edge contacts 350.

As can be seen in FIG. 3B, each of the first microelectronic elements 320 can be configured to receive the command and address information through the same CA contacts 371 of the first contacts 351, and each of the second microelectronic elements 330 can be configured to receive the command and address information through the same CA contacts 372 of the second contacts 352. However, the first microelectronic elements 320a and 320b have respective first and second delays from the group of CA contacts 371 of the first contacts 351, the second delay being greater than the first delay, and the second microelectronic elements 330a and 330b have respective third and fourth delays from the group of CA contacts 372 of the second contacts 352, the fourth delay being greater than the third delay.

FIGS. 4A and 4B illustrate a DIMM 410, according to another variation of the DIMM 10 of FIGS. 1A and 1B. Elements of the DIMM 410 that are not specifically described below can be the same as those described above with respect to the DIMM 10. The DIMM 410 has first and second microelectronic elements 420, 430 arranged in a single common plane parallel to the first surface 441 of the module card 440, similar to the arrangement of first and second microelectronic elements 220, 320 of the DIMM 210.

In the example of FIGS. 4A and 4B, the edge contacts 450 can include two groups of command and address information contacts (“CA contacts”) 471 and 472, labeled in FIG. 4B as CA_0 and CA_1, respectively. In one example (shown in FIG. 9B), the two groups of CA contacts 471 and 472 can occupy 48 contacts (24 per channel) of the at least 288 edge contacts 450.

The DIMM 410 can include a registering clock driver (“RCD”) element 480 electrically connected with the first and second contacts 451, 452, at least one of the first microelectronic elements 420, and at least one of the second microelectronic elements 430. The RCD element 480 can be configured to regenerate all of the command and address information received at the first and second contacts 451, 452. The RCE element 480 can provide “buffering” of command and address information received at the first and second contacts 451, 452. Such an RCD element can be configured to help provide impedance isolation for each of the microelectronic elements 420, 430 with respect to components external to the DIMM 410.

Similar to the DIMM 310, the DIMM 410 can illustrate principles of interconnection that support an in-module “fly-by” CA signaling configuration. The first microelectronic elements 420a and 420b can have respective first and second delays from the group of CA contacts 471 of the first contacts 451, the second delay being greater than the first delay, and the second microelectronic elements 430a and 430b can have respective third and fourth delays from the group of CA contacts 472 of the second contacts 452, the fourth delay being greater than the third delay.

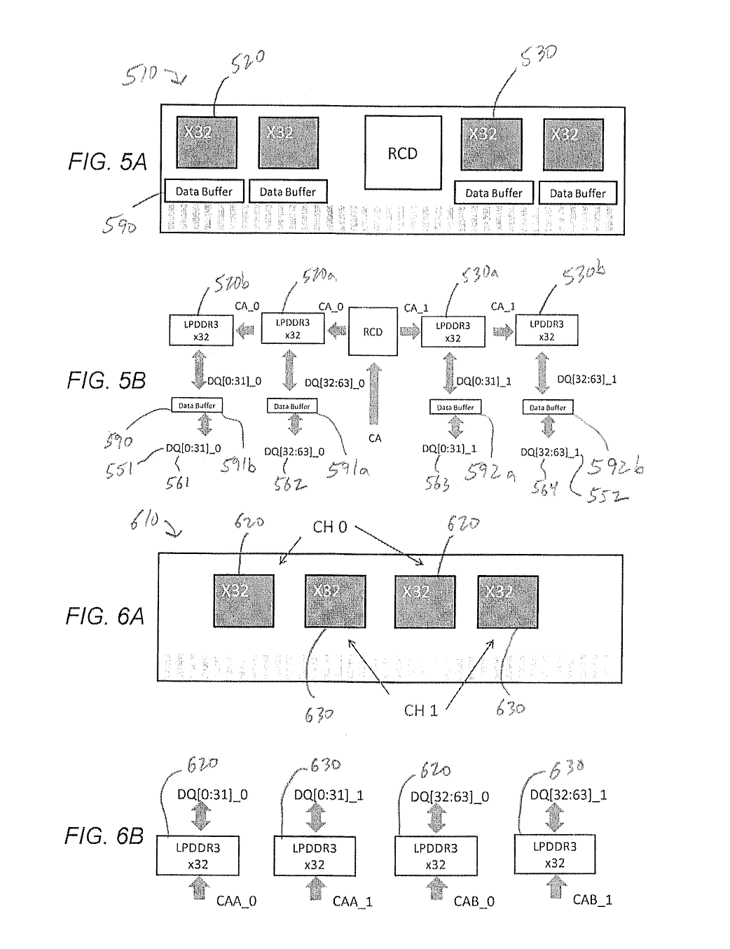

FIGS. 5A and 5B illustrate a DIMM 510, according to a variation of the DIMM 410 of FIGS. 4A and 4B. Elements of the DIMM 510 that are not specifically described below can be the same as those described above with respect to the DIMM 410. The DIMM 510 can include a plurality of data buffer elements 590 electrically connected with the first and second contacts 551, 552, at least one of the first microelectronic elements 520, and at least one of the second microelectronic elements 530.

Each buffer element 590 can be configured to regenerate all of the data signals received at the first and second contacts 551, 552. The buffer elements 590 can provide “buffering” of data signals received at the first and second contacts 551, 552. Such data buffer elements can be configured to help provide impedance isolation for each of the microelectronic elements 520, 530 with respect to components external to the DIMM 510.

In the example shown in FIGS. 5A and 5B, the DIMM 510 can include four buffer elements 591b, 591a, 592a, and 592b, each electrically connected to a respective group of data contacts 561, 562, 563, and 564 and configured to transfer 32 bits twice per clock cycle to a respective one of the microelectronic elements 520b, 520a, 530a, and 530b.

FIGS. 6A and 6B illustrate a DIMM 610, according to a variation of the DIMM 210 of FIGS. 2A and 2B. Elements of the DIMM 610 that are not specifically described below can be the same as those described above with respect to the DIMM 210. The DIMM 610 has first and second microelectronic elements 620, 630, but rather than being arranged with the first microelectronic elements adjacent one another and the second microelectronic elements adjacent one another, the first microelectronic elements 620 that are configured to carry command and address information and data signals corresponding to a first memory channel (labeled “CH 0” in FIG. 6A) are separated from one another by one of the second microelectronic elements 630, and the second microelectronic elements 630 that are configured to carry command and address information and data signals corresponding to a second memory channel (labeled “CH 1” in FIG. 6A) are separated from one another by one of the first microelectronic elements 620.

FIGS. 7A and 7B illustrate a DIMM 710, according to another variation of the DIMM 10 of FIGS. 1A and 1B. Elements of the DIMM 710 that are not specifically described below can be the same as those described above with respect to the DIMM 10. The DIMM 710 has first and second microelectronic elements 720, 730, but rather than having the edge contacts configured to transfer 32 bits twice per clock cycle to each of the first and second microelectronic elements, the edge contacts 750 are configured to transfer 16 bits twice per clock cycle to each of the first and second microelectronic elements.

In the example of FIGS. 7A and 7B, the DIMM 710 can include four first microelectronic elements 720 and four second microelectronic elements 730, which can be arranged in first and second stacks 721a, 721b of first microelectronic elements and third and fourth stacks 731a, 731b of second microelectronic elements overlying a first surface 741 of the module card 740.

The first contacts 751 can be configured to transfer 16 bits twice per clock cycle to each of the first microelectronic elements 720, and the second contacts 752 can be configured to transfer 16 bits twice per clock cycle to each of the second microelectronic elements 730. This can be seen in FIG. 7B, in which the contacts 750 can include eight 16-bit groups of data contacts 761-768, labeled in FIG. 7B as DQ(0:15)_0, DQ(15:31)_0, DQ(32:47)_0, DQ(48:63)_0, DQ(0:15)_1, DQ(15:31)_1, DQ(32:47)_1, and DQ(48:63)_1, respectively. In one example, the eight groups of data contacts 761-768 can occupy 128 contacts (64 per channel) of the at least 288 edge contacts 750.

In the example of FIGS. 7A and 7B, the edge contacts 750 can also include four groups of command and address information contacts 771, 772, 773, and 774, labeled in FIG. 7B as CAA_0, CAB_0, CAA_1, and CAB_1, respectively. In one example, the four groups of CA contacts 771, 772, 773, and 774 can occupy 96 contacts (24 per CA contact group, 48 per channel) of the at least 288 edge contacts 750.

As can be seen in FIG. 7B, each of the first microelectronic elements 720 in the first stack 721a can be configured to receive the command and address information through the same first group of CA contacts 771 of the first contacts 751, and each of the first microelectronic elements in the second stack 721b can be configured to receive the command and address information through the same second group of CA contacts 772 of the first contacts. Also, each of the second microelectronic elements 730 in the third stack 731a can be configured to receive the command and address information through the same third group of CA contacts 773 of the second contacts 752, and each of the second microelectronic elements in the fourth stack 731b can be configured to receive the command and address information through the same fourth group of CA contacts 774 of the second contacts.

FIGS. 8A and 8B illustrate a DIMM 810, according to another variation of the DIMM 10 of FIGS. 1A and 1B. Elements of the DIMM 810 that are not specifically described below can be the same as those described above with respect to the DIMM 10. The DIMM 810 has first and second microelectronic elements 820, 830, but rather than having the edge contacts configured to transfer 32 bits twice per clock cycle to each of the first and second microelectronic elements simultaneously in a single rank access, the edge contacts 850 can be configured to transfer 32 bits twice per clock cycle to one microelectronic element in each stack of the first and second microelectronic elements simultaneously, and each of the stacks can be configured to provide sequential dual rank access to memory storage array locations in the respective stack.

In the example of FIGS. 8A and 8B, the DIMM 810 can include four first microelectronic elements 820 and four second microelectronic elements 830, which can be arranged in first and second stacks 821a, 821b of first microelectronic elements and third and fourth stacks 831a, 831b of second microelectronic elements overlying a first surface 841 of the module card 840.

The first contacts 851 can be configured to transfer 32 bits twice per clock cycle to each of the first microelectronic elements 820, and the second contacts 852 can be configured to transfer 32 bits twice per clock cycle to each of the second microelectronic elements 830. This can be seen in FIG. 8B, in which the contacts 850 can include four 32-bit groups of data contacts 861, 862, 863, and 864, labeled in FIG. 8B as DQ(0:31)_0, DQ(32:63)_0, DQ(0:31)_1, and DQ(32:63)_1, respectively. In one example, the four groups of data contacts 861, 862, 863, and 864 can occupy 128 contacts (64 per channel) of the at least 288 edge contacts 850.

Within each of the stacks 821a, 821b of the first microelectronic elements 820, sequential dual rank access to memory storage array locations in the stacks can be provided by two chip select contacts 881, 882 of the first contacts 851. To access memory storage array locations in first microelectronic elements 820a, 820c, a first chip select contact 881 (labeled in FIG. 8B as CS0_0) can be energized, and to access memory storage array locations in first microelectronic elements 820b, 820d, a second chip select contact 882 (labeled in FIG. 8B as CS1_0) can be energized. Therefore, the first microelectronic elements 820 can comprise a first channel of 64-bit memory access, but with two ranks: the first rank comprising microelectronic elements 820a and 820c, and the second rank comprising microelectronic elements 820b and 820d.

Similarly, within each of the stacks 831a, 831b of the second microelectronic elements 830, sequential dual rank access to memory storage array locations in the stacks can be provided by two chip select contacts 883, 884 of the second contacts 852. To access memory storage array locations in second microelectronic elements 830a, 830c, a third chip select contact 883 (labeled in FIG. 8B as CS0_1) can be energized, and to access memory storage array locations in second microelectronic elements 830b, 830d, a fourth chip select contact 884 (labeled in FIG. 8B as CS1_1) can be energized. Therefore, the second microelectronic elements 830 can comprise a second channel of 64-bit memory access, but with two ranks: the first rank comprising microelectronic elements 830a and 830c, and the second rank comprising microelectronic elements 830b and 830d.

In the example of FIGS. 8A and 8B, the edge contacts 850 can also include four groups of command and address information contacts 871, 872, 873, and 874, labeled in FIG. 8B as CAA_0, CAB_0, CAA_1, and CAB_1, respectively. In one example, the four groups of CA contacts 871, 872, 873, and 874 can occupy 96 contacts (24 per CA contact group, 48 per channel) of the at least 288 edge contacts 850.

As can be seen in FIG. 8B, each of the first microelectronic elements 820 in the first stack 821a can be configured to receive the command and address information through the same first group of CA contacts 871 of the first contacts 851, and each of the first microelectronic elements in the second stack 821b can be configured to receive the command and address information through the same second group of CA contacts 872 of the first contacts. Also, each of the second microelectronic elements 830 in the third stack 831a can be configured to receive the command and address information through the same third group of CA contacts 873 of the second contacts 852, and each of the second microelectronic elements in the fourth stack 831b can be configured to receive the command and address information through the same fourth group of CA contacts 874 of the second contacts.

FIGS. 9A and 9B illustrate a DIMM 910, according to a variation of the DIMM 310 of FIGS. 3A and 3B. Elements of the DIMM 910 that are not specifically described below can be the same as those described above with respect to the DIMM 310. The DIMM 910 has first and second microelectronic elements 920, 930, as well as error-correcting code (“ECC”) microelectronic elements 980. The DIMM 910 has first and second microelectronic elements 920, 930 and the ECC microelectronic elements 980 arranged in a single common plane parallel to the first surface 941 of the module card 940.

As can be seen in FIG. 9B, each of the first microelectronic elements 920 and a first EEC microelectronic element 980a can be configured to receive the command and address information through the same CA contacts 971 of the first contacts 951, and each of the second microelectronic elements 930 and the second EEC microelectronic elements 980b can be configured to receive the command and address information through the same CA contacts 972 of the second contacts 952. However, the first microelectronic elements 920a, 920b, 980a have respective first, second, and third delays from the group of CA contacts 971 of the first contacts 951, the third delay being greater second delay, which is greater than the first delay, and the second microelectronic elements 930a, 930b, 980b have respective fourth, fifth, and sixth delays from the group of CA contacts 972 of the second contacts 952, the sixth delay being greater than the fifth delay, which is greater than the fourth delay.

The first contacts 951 can be configured to transfer 32 bits twice per clock cycle to each of the first microelectronic elements 920 and 8 bits twice per clock cycle to the first EEC microelectronic element 980a, for a total of 72 bits per clock cycle configured to implement the first memory channel CH 0, and the second contacts 952 can be configured to transfer 32 bits twice per clock cycle to each of the second microelectronic elements 930 and 8 bits twice per clock cycle to the second EEC microelectronic element 980b, for a total of 72 bits per clock cycle configured to implement the second memory channel CH 1. This can be seen in FIG. 9B, in which the contacts 950 can include four 32-bit groups of data contacts, labeled in FIG. 9B as DQ(0:31)_0, DQ(32:63)_0, DQ(0:31)_1, and DQ(32:63)_1, respectively, and two 8-bit groups of data contacts, labeled as DQ(64:71)_0 and DQ(64:71)_1. In one example, the four groups of 32-bit data contacts and the two groups of 8-bit data contacts can occupy 144 contacts (72 per channel) of the at least 288 edge contacts 950.

Although the ECC microelectronic elements 980 are shown in a variation of the DIMM 310 of FIGS. 3A and 3B, EEC microelectronic elements as described above can be included in any of the other embodiments described herein, transferring an additional 8 bits of error-correcting code twice per clock cycle from corresponding data contacts for each of the two memory channels CH 0 and CH 1.

FIG. 10A is a side view of a module card 1040 that can be used in any of the embodiments of FIGS. 1A through 8B. In the example shown in FIG. 10A, the module card 1040 has 288 edge contacts 1050 at an insertion edge 1043 of the module card. The edge contacts 1050 can be at the first surface 1041, the second opposite surface, or both the first and second surfaces.

FIG. 10B is a chart of the number of pins assigned to various functions according to a particular example of the embodiment of FIGS. 1A and 1B, as well as some of the other embodiments described herein. The chart of FIG. 10B includes 88 edge contacts per channel configured to carry data signals, for 176 total data contacts out of the 288 edge contacts 1050 of the embodiment of FIG. 10A. The chart of FIG. 10B also includes 24 edge contacts per channel configured to carry command and address information, for 48 total CA contacts out of the 288 edge contacts 1050. The chart of FIG. 10B also includes 8 edge contacts per channel configured to carry reference voltage, reserved supply, SPD supply, and SPD use, for 16 total contacts out of the 288 edge contacts 1050. With 232 of the 288 edge contacts accounted for above, this leaves 56 edge contacts out of the 288 edge contacts 1050 for power and ground, which permits a signal to power/ground ratio of about 4:1.

The microelectronic packages, circuit panels, and microelectronic assemblies described above with reference to FIGS. 1A through 10B above can be utilized in construction of diverse electronic systems, such as the system 1100 shown in FIG. 11. For example, the system 1100 in accordance with a further embodiment of the invention includes a plurality of modules or components 1106 such as the packages, circuit panels, and assemblies as described above, in conjunction with other electronic components 1108, 1110 and 1111.

The system 1100 can include a plurality of sockets 1105, each socket including a plurality of contacts 1107 at one or both sides of the socket, such that each socket 1105 can be suitable for mating with corresponding edge contacts or module contacts of a corresponding module or component 1106. In the exemplary system 1100 shown, the system can include a circuit panel, motherboard, or riser panel 1102 such as a flexible printed circuit board, and the circuit panel can include numerous conductors 1104, of which only one is depicted in FIG. 11, interconnecting the modules or components 1106, 1108, 1110, 1111 with one another. Such a circuit panel 1102 can transport signals to and from each of the modules or components 1106 included in the system 1100. However, this is merely exemplary; any suitable structure for making electrical connections between the modules or components 1106 can be used.

In a particular embodiment, the system 1100 can also include a processor such as the semiconductor chip 1108, such that each module or component 1106 can be configured to transfer a number N of data bits in parallel twice per clock cycle, and the processor can be configured to transfer a number M of data bits in parallel twice per clock cycle, M being equal to or greater than N.

In one example, the system 1100 can include a processor chip 1108 that is configured to transfer sixty-four data bits in parallel twice per clock cycle, and the system can also include a module 1106 such as the module 10 described with reference to FIGS. 1A and 1B, the module 1106 configured to transfer sixty-four data bits in parallel twice per clock cycle (i.e., the module 1106 can include first and second memory channels, the microelectronic elements in each of the two memory channels being configured to transfer sixty-four data bits in parallel twice per clock cycle).

In the example depicted in FIG. 11, the component 1108 is a semiconductor chip and component 1110 is a display screen, but any other components can be used in the system 1100. Of course, although only two additional components 1108 and 1110 are depicted in FIG. 11 for clarity of illustration, the system 1100 can include any number of such components.

Modules or components 1106 and components 1108 and 1110 can be mounted in a common housing 1101, schematically depicted in broken lines, and can be electrically interconnected with one another as necessary to form the desired circuit. The housing 1101 is depicted as a portable housing of the type usable, for example, in a cellular telephone or personal digital assistant, and screen 1110 can be exposed at the surface of the housing. In embodiments where a structure 1106 includes a light-sensitive element such as an imaging chip, a lens 1111 or other optical device also can be provided for routing light to the structure. Again, the simplified system shown in FIG. 11 is merely exemplary; other systems, including systems commonly regarded as fixed structures, such as desktop computers, routers and the like can be made using the structures discussed above.

It will be appreciated that the various dependent claims and the features set forth therein can be combined in different ways than presented in the initial claims. It will also be appreciated that the features described in connection with individual embodiments may be shared with others of the described embodiments.

Although the invention herein has been described with reference to particular embodiments, it is to be understood that these embodiments are merely illustrative of the principles and applications of the present invention. It is therefore to be understood that numerous modifications may be made to the illustrative embodiments and that other arrangements may be devised without departing from the spirit and scope of the present invention as defined by the appended claims.

1. A dual inline memory module (“DIMM”), comprising:
a module card having first and second opposed surfaces, and a plurality of parallel edge contacts adjacent an edge of at least one of the first and second surfaces for mating with corresponding contacts of a socket when the module is inserted in the socket, the edge contacts including first contacts and second contacts, the first contacts configured to carry command and address information and data signals corresponding to a first memory channel, and the second contacts configured to carry command and address information and data signals corresponding to a second memory channel independent from the first memory channel; and
a plurality of microelectronic elements each having a surface facing a surface of the first and second surfaces of the module card, each microelectronic element having memory storage array function being of type LPDDRx and being configured to sample the command and address information at least twice per clock cycle, the plurality of microelectronic elements comprising first microelectronic elements configured to implement the first memory channel and second microelectronic elements configured to implement the second memory channel,
wherein the first microelectronic elements are configured for communication via the first contacts, and the second microelectronic elements are configured for communication via the second contacts.

2. The DIMM of claim 1, wherein the plurality of microelectronic elements comprises two first microelectronic elements and two second microelectronic elements, the first contacts are configured to transfer 32 bits twice per clock cycle to each of the first microelectronic elements, and the second contacts are configured to transfer 32 bits twice per clock cycle to each of the second microelectronic elements.

3. The DIMM of claim 1, wherein the first and second microelectronic elements are arranged in respective first and second stacks, each of the first microelectronic elements are configured to receive the command and address information through the same first contacts, and each of the second microelectronic elements are configured to receive the command and address information through the same second contacts.

4. The DIMM of claim 1, wherein the surface of each of the microelectronic elements is arranged in a single common plane parallel to the first surface of the module card.

5. The DIMM of claim 1, wherein the plurality of microelectronic elements comprises two or more first microelectronic elements and two or more second microelectronic elements, one or more of the first microelectronic elements is configured to receive the command and address information through a first group of the first contacts, and one or more of the first microelectronic elements is configured to receive the command and address information through a second group of the first contacts.

6. The DIMM of claim 1, wherein the plurality of microelectronic elements comprises two first microelectronic elements and two second microelectronic elements, the surface of each of the microelectronic elements is arranged in a single common plane parallel to the first surface of the module card, each of the first microelectronic elements are configured to receive the command and address information through the same first contacts, and each of the second microelectronic elements are configured to receive the command and address information through the same second contacts, and
wherein the two first microelectronic elements have respective first and second delays from the first contacts, the second delay being greater than the first delay, and the two second microelectronic elements have respective third and fourth delays from the second contacts, the fourth delay being greater than the third delay.

7. The DIMM of claim 1, further comprising a registering clock driver (“RCD”) element electrically connected with the first and second contacts, at least one of the first microelectronic elements, and at least one of the second microelectronic elements, wherein the RCD element is configured to regenerate all of the command and address information received at the first and second contacts.

8. The DIMM of claim 7, further comprising a plurality of data buffer elements electrically connected with the first and second contacts, at least one of the first microelectronic elements, and at least one of the second microelectronic elements, wherein each buffer element is configured to regenerate all of the data signals received at the first and second contacts.

9. The DIMM of claim 1, wherein the surface of each of the microelectronic elements is arranged in a single common plane parallel to the first surface of the module card, the first microelectronic elements are separated from one another by one of the second microelectronic elements, and the second microelectronic elements are separated from one another by one of the first microelectronic elements.

10. The DIMM of claim 1, wherein the plurality of microelectronic elements comprises four first microelectronic elements and four second microelectronic elements, the first contacts are configured to transfer 16 bits twice per clock cycle to each of the first microelectronic elements, and the second contacts are configured to transfer 16 bits twice per clock cycle to each of the second microelectronic elements.

11. The DIMM of claim 1, wherein the first microelectronic elements are arranged in first and second stacks, the second microelectronic elements are arranged in third and fourth stacks, the microelectronic elements in the first and second stacks are configured to receive the command and address information through first and second groups of the first contacts, respectively, and the microelectronic element in the third and fourth stacks are configured to receive the command and address information through third and fourth groups of the second contacts, respectively.

12. The DIMM of claim 1, wherein the first microelectronic elements are arranged in first and second stacks, the second microelectronic elements are arranged in third and fourth stacks, the microelectronic elements in the first and second stacks are configured to receive the command and address information and the data signals through first and second groups of the first contacts, respectively, and the microelectronic element in the third and fourth stacks are configured to receive the command and address information and the data signals through third and fourth groups of the second contacts, respectively,
wherein each of the stacks is configured to provide sequential dual rank access to memory storage array locations in the respective stack.

13. The DIMM of claim 12, wherein each of the microelectronic elements in the first stack are configured to receive the command and address information and data signals through the same first contacts in the first group, and each of the microelectronic elements in the second stack are configured to receive the command and address information and data signals through the same first contacts in the second group, and
wherein each of the microelectronic elements in the third stack are configured to receive the command and address information and data signals through the same second contacts in the third group, and each of the microelectronic elements in the fourth stack are configured to receive the command and address information and data signals through the same second contacts in the fourth group.

14. The DIMM of claim 1, wherein the plurality of microelectronic elements comprises two first microelectronic elements, two second microelectronic elements, a first ECC microelectronic element, and a second ECC microelectronic element, the first contacts are configured to transfer 32 bits twice per clock cycle to each of the first microelectronic elements and 8 bits twice per clock cycle to the first ECC microelectronic element, and the second contacts are configured to transfer 32 bits twice per clock cycle to each of the second microelectronic elements and 8 bits twice per clock cycle to the second ECC microelectronic element.

15. The DIMM of claim 1, wherein the plurality of parallel edge contacts includes at least 288 parallel edge contacts.

16. The DIMM of claim 1, wherein the command signals are write enable, row address strobe, column address strobe, activate, and parity signals.

17. The DIMM of claim 1, wherein each of the microelectronic elements embodies a greater number of active devices to provide memory storage array function than any other function.

18. A system comprising the DIMM of claim 1, a circuit panel, and a processor, the edge contacts of the DIMM being inserted into a mating socket electrically connected with the circuit panel.

19. A system comprising the DIMM of claim 1 and one or more other electronic components electrically connected to the DIMM.

20. The system of claim 19, further comprising a housing, the DIMM and the one or more other electronic components being assembled with the housing.
